(19) United States
(12) Patent Application Publication
(10) Pub. No.: US 2017/0133527 A1
(43) Pub. Date: May 11, 2017

(54) METHOD FOR THE PREPARATION OF A TRANSPARENT AND CONDUCTIVE AUTO-SUPPORTED SILVER NANOWIRE FILM AND APPLICATIONS THEREOF

(71) Applicant: CENTRE NATIONAL DE LA RECHERCHE SCIENTIFIQUE, PARIS (FR)

(72) Inventors: Rénal BACKOV, BORDEAUX-CAUDERAN (FR); Philippe POULIN, TALENCE (FR); Jonathan IDIER, TALENCE (FR)

(21) Appl. No.: 15/323,113

(22) PCT Filed: Jul. 15, 2014
(86) PCT No.: PCT/IB2014/001448

§ 371 Date: Dec. 30, 2016

(51) Int. Cl. H01L 31/0224; H01L 31/18

(52) U.S. Cl. CPC H01L 31/022491; H01L 31/1884

(57) ABSTRACT

The invention generally relates to the field of transparent electrodes. In particular, the invention relates to a method for producing a transparent and conducting auto-supported silver nanowire film, to the transparent and conducting silver nanowire film obtained by said method and to the use of said film as a transparent and flexible electrode in an electric device, in particular in a photovoltaic cell (solar cell).

The invention generally relates to the field of transparent electrodes. In particular, the invention relates to a method for producing a transparent and conducting auto-supported silver nanowire film, to the transparent and conducting silver nanowire film obtained by said method and to the use of said film as a transparent and flexible electrode in an electric device, in particular in a photovoltaic cell (solar cell).

Transparent electrodes are used in a large range of applications such as plasma screens, liquid crystal displays, touch screens, Organic Light-Emitting Devices (OLEDs), solar cells . . . .

Most of transparent electrodes are currently made of inorganic materials such as indium tin oxide (ITO). However, ITO is brittle, cannot be bent and its process of deposition is very costly. Moreover, indium is getting scarce. That is why alternative solutions, such as films made by liquid deposition of carbon nanotubes or silver nanowires (AgNWs), have been investigated for a few years. Challenges in the field consist in assembling the materials in order to achieve optimized compromises of transparency and sheet-resistance.

Because of their metallic nature, silver nanowires are promising candidates to replace ITO thanks to their high conductivity at room temperature and the possibility to deposit them onto plastic substrates such as Poly(Ethylene Terephtalate) (PET). Their one-dimensional structure plays an important role in these performances as the percolation threshold can be reached for low concentration of materials. However, silver nanowires get oxidized in time when exposed in air and their performances decrease quickly.

Different solutions have already been proposed to prevent oxidation of silver nanowires. For examples, previous works report the use of graphene/AgNWs (Ruiyi Chen et al., Adv. Funct. Mater, 2013, 23, 5150-5158), reduced graphene oxide/AgNWs (Yumi Ahn et al., Appl. Mater. Interfaces, 2012, 4, 6410-6414), polycarbonate/AgNWs composites (Ivan Moreno et al., Nanotechnology, 2013, 24, 275603) or of coating of AgNWs with an oxidation protection layer made from an oxide such as titanium dioxide TiO₂ (US patent application No 2014/0020737) resulting in an oxidation stability for a few months. Nevertheless, these different solutions are not fully satisfactory since these protective layers tend to reduce the conductivity and transmittance of the electrodes.

It remains therefore critical to find new approaches that allow protection against oxidation silver nanowires when used to prepare transparent conductive films without downgrading electro-optical properties of the corresponding electrodes.

The present invention has thus for first object, a method for producing a transparent and conductive auto-supported silver nanowire film, said method comprising at least the following steps:

1) a first step of preparing a dispersion of silver nanowires in a liquid medium comprising at least one solvent and triphenylphosphine (TPP) or a derivative thereof,

2) a second step of depositing the dispersion obtained in step 1) onto a substrate to obtain an assembly comprising a silver nanowire film supported on said substrate,

3) a third step of drying the assembly obtained in step 2) to obtained a dried assembly,

4) a fourth step of separating the silver nanowire film from the substrate of the dried assembly obtained in step 3) to obtain a transparent and conductive auto-supported silver nanowire film.

As it is demonstrated in the example illustrating the present invention, the use of triphenylphosphine (TPP) as a stabilizing agent makes it possible to lead, in a simple and economic manner, to silver nanowires films which are resistant to oxidation and that without altering their intrinsic properties such as transmittance and sheet resistance. In particular, and thanks to its affinity with silver nanowires, TPP molecules form a thin oxidation protection layer and do not interfere with the electrical conductivity along the wires. The resulting silver nanowires films are stable in air more than three months and the sheet resistance does not change during this period (12 Ω/sq. and 75% transmittance). Stability is also demonstrated in highly oxidative medium such as nitric acid atmosphere. The present invention satisfies an important technological demand for the development of new and efficient transparent and flexible electrodes. It is industrially viable since TPP is a low cost material that can be easily combined with silver nanowire to lead easily to transparent and flexible electrodes.

Silver nanowires used according to step 1) of the present method are preferably chosen among those having a mean diameter ranging from 5 to 200 nm (more preferably from 25 to 60 nm) and a length ranging from 1 to 100 μm (more preferably from 10 to 75 μm).

Silver nanowires are commercially available products. It can for example be mentioned those sold under the trade names Silver Nanowire AgNW-25, Silver Nanowire AgNW-60, Silver Nanowire AgNW-115 and Silver Nanowire AgNW-130 by the firm Seashell Technologies.

The liquid medium used to disperse the silver nanowires during step 1) is preferably chosen among water, isopropyl alcohol, ethylene glycol and epoxy resin. According to a preferred embodiment of the invention method, the liquid medium is isopropyl alcohol.

The amount of silver nanowires in the dispersion of step 1) preferably varies from about 0.1 to 4 mg·mL⁻¹, and more preferably from about 0.1 to 1 mg·mL⁻¹.

According to the invention, the expression derivatives of triphenylphosphine encompasses triphenylphosphines which comprise one or more substituents on at least one phenyl ring such substituents being for example chosen among alkyl groups, alkoxy groups, etc. . . . . As example of derivatives of triphenylphosphine, it can be mentioned Bis(2,4-dimethoxyphenyl)phenylphosphine, (méthylphényl)diphenylphosphine and 1,2-bis(diphenylphosphino)ethane.

The amount of triphenylphosphine in the dispersion of step 1) preferably varies from about 0.05 to 2 mg·mL⁻¹, and more preferably from about 0.11 to 1.1 mg·mL⁻¹.

According to a preferred embodiment of the present method, the weight ratio of silver nanowires to TPP varies from about 2:1 to 1:2, and more preferably from about 1:1 to 1:2.

The first step is preferably carried out under mechanical agitation (stirring).

The deposition of the dispersion obtained at step 1) onto the substrate can be carried out by filtering, spray coating, roll coating, dip coating, printing, transfer stamping, etc, depending on the nature of the substrate.

According to a particulate embodiment of the present method, the substrate is a porous filter and step 2) is carried out by filtering of the dispersion obtained in step 1) onto said porous filter.

In that case, the pores of said porous filter have preferably an average diameter ranging from 0.02 μm to 0.2 μm, and more preferably of 0.2 μm. As examples of such a porous filter, it can be mentioned anodized aluminum oxide (AAO) membranes, nylon/polyamide membranes, polytetrafluoroethylene membranes, and mixed cellulose ester membranes. The use of an anodized aluminum oxide (AAO) membrane is preferred according to the invention.

The filtering step is then preferably carried out under vacuum.

The drying of step 3) can be performed by heat treatment of the assembly obtained in step 2) in air, at a temperature preferably ranging from about 60 to 90° C., and for a period of time varying from about 5 to 30 minutes.

The fourth step of separating the silver nanowires film from the substrate can be performed by any method allowing the recovery of the auto-supported silver nanowires film, such as for example peeling the silver nanowire film from the substrate, or dissolving the substrate of the dried assembly obtained in step 3) in a dissolving medium.

According to a particulate embodiment of the present method, and when the substrate used in step 2) is an anodized aluminum oxide filter, step 4) is preferably carried out by immersion of the dried assembly into a liquid medium which is able to dissolve said filter. For example, said liquid medium is an alkalinizing agent such as sodium hydroxide (NaOH) or potassium hydroxide (KOH).

According to this particulate embodiment, the method of the invention further comprises a fifth step of rinsing and drying the auto-supported silver nanowires film. In that case, the rinsing of step 5) is preferably carried out with deionized water until to reach a neutral pH.

The drying of step 5) can be carried out in the same conditions of temperature and time than the drying of step 3) preferably after the auto-supported silver nanowire film has been transferred onto a solid substrate, such as for example onto a poly(ethylene terephtalate) (PET substrate).

The auto-supported silver nanowires films obtained at the end of the present method can be stored at ambient temperature without any particular precaution.

Another object of the present invention is the transparent and conductive auto-supported silver nanowires film directly obtained by the method disclosed in the first object of the invention, wherein said film comprises a web of percolated silver nanowires, wherein the surface of said nanowires is coated by an oxidation resistant layer comprising triphenylphosphine or a derivative thereof.

The thin films can be characterized by UV-visible measurements (transmittance), by atomic force microscopy (AFM) to evaluate their roughness and thickness, by high-resolution scanning electron microscopy (HR-SEM) to evaluate their morphology, and by four-probe measurements to evaluate their sheet resistance.

The auto-supported silver nanowires films have a thickness preferably ranging from about 10 nm to 300 nm.

The auto-supported silver nanowires films according to the invention can advantageously be used as a transparent and flexible electrode.

Therefore, a third object of the present invention is the use of an auto-supported silver nanowires film directly obtained by the method described in the first object of the present invention or as defined according to the second object of the present invention, as a transparent and flexible electrode in an electric device. In particular the auto-supported silver nanowire film of the invention can be used as a transparent and flexible electrode in a photovoltaic cell (solar cell), in plasma screens, in liquid crystals displays, in touch screens, or in organic light-emitting devices (OLEDs).

A fourth objet of the present invention is therefore an electric device comprising at least one auto-supported silver nanowires film directly obtained by the method described in the first object of the present invention or as defined according to the second object of the present invention, as a transparent and flexible electrode.

Hereinafter, the present invention will be additionally described based on the following examples which are given not limiting in any manner.

### EXAMPLES

The raw materials used in the examples are listed below:
Silver nanowires (average diameter 26 nm, average length 24 μm) sold under the trade name Silver Nanowire AgNW-25 from Seashell Technologies at a concentration of 5.4 mg·mL⁻¹ in isopropyl alcohol,
Triphenylphosphine (Aldrich, 99%)

All other products used in these examples were of analytical grade. These raw materials have been used as received from the manufacturers, without any step of purification, unless otherwise stipulated.

### Example 1: Preparation and Properties of Transparent and Conductive Silver Nanowire Films According to the Method of the Invention

In this example, different silver nanowire transparent and conductive films have been prepared according to the method of the invention, i.e. using triphenylphosphine (TPP) as an agent for preventing oxidation of the silver nanowires (AgNW-TPP films). A comparative silver nanowire transparent and conductive film has also been prepared according to a method not forming part of the present invention, i.e. without using triphenylphosphine as an agent for preventing oxidation of the silver nanowires (AgNW film). They have then been compared with regards to their respective optical properties, sheet resistivity and resistance to accelerated oxidation.

The dispersion of silver nanowires as purchased was then diluted with isopropyl alcohol to obtain a concentration of silver nanowires of 0.054 mg·mL⁻¹. This diluted dispersion of silver nanowires was then used in the overall process.

A triphenylphosphine (Aldrich, 99%) solution at 3.4 mg·mL⁻¹ in isopropyl alcohol was prepared.

Silver nanowires and silver nanowires+triphenylphosphine dispersions were then prepared as follows:
Dispersion 1: 0.5 mg of Silver nanowires without TPP
Dispersion 2: 0.5 mg of silver nanowires+0.55 mg of TPP,
Dispersion 3: 0.1 mg of silver nanowires without TPP,
Dispersion 4: 0.1 mg of silver nanowires+0.11 mg of TPP.

Each of the dispersions was vacuum filtered on an Anodized Aluminium Oxide (AAO) filter (47 mm, 0.02 μm, Whatman).

The resulting film+membrane assembly was then dried during 5 minutes at 60° C. in air. The film transfer was carried out by dissolving the alumina membrane with a NaOH solution and deposition of the film onto a PET substrate.

To do so, 20 mL of a 1.5M NaOH solution was prepared and put in a Petri dish. The alumina membrane was firstly put on deionized water to fill the pores with water and drive the dissolution softer. The wet membrane was then put on the NaOH solution and dissolved within 15 minutes. The solution was partially taken out of the Petri dish, as well as the alumina fragments. The solution has been changed several times with deionized water in order to reach a neutral pH.

A 5×5 cm² PET substrate was put at the bottom of the Petri dish. The remaining water was taken out with a pipette, allowing the film to deposit onto the PET membrane. The PET supporting the films was then dried at 60° C. in air.

4 films were prepared respectively with Dispersions 1 to 4:
Film called 0.5AgNW-0TPP not forming part of the present invention, i.e. prepared with Dispersion 1 comprising only silver nanowires and no TPP;
Film called 0.5AgNW-0.55TPP according to the invention, i.e. prepared with Dispersion 2 comprising both silver nanowires and TPP;
Film called 0.1AgNW-0TPP not forming part of the present invention, i.e. prepared with Dispersion 3 comprising only silver nanowires and no TPP; and
Film called 0.1AgNW-0.11TPP according to the invention, i.e. prepared with Dispersion 4 comprising both silver nanowires and TPP.

In these denominations, the numbers correspond to the mass (in mg) of each component used in the dispersion. These films were stored in normal conditions of pressure and temperature

The transmittance and sheet resistivity measurements were tested on films 0.5AgNW-0TPP and 0.5AgNW-0.55TPP.

The transmittance of the films was measured at a wavelength of 550 nm with a Cary 100 Bio UV-vis spectrophotometer.

The sheet resistivity of the films was measured with a four-point probe method as a function of time. Four equidistant gold electrodes are evaporated through a mask all along the substrates prior to carrying out the measurements. An electrical assembly composed of four flexible “conductive fingers” has been used. These “fingers” are put in touch with the gold electrodes. Current is applied to the external electrodes while voltage is measured at the central electrodes (range of current from a few nA to some mA is applied). The use of Ohm's law gives resistance which is converted in sheet resistance by normalizing it with the ratio of the length to the spacing of the electrodes.

For both, measurements have been carried out for 108 days.

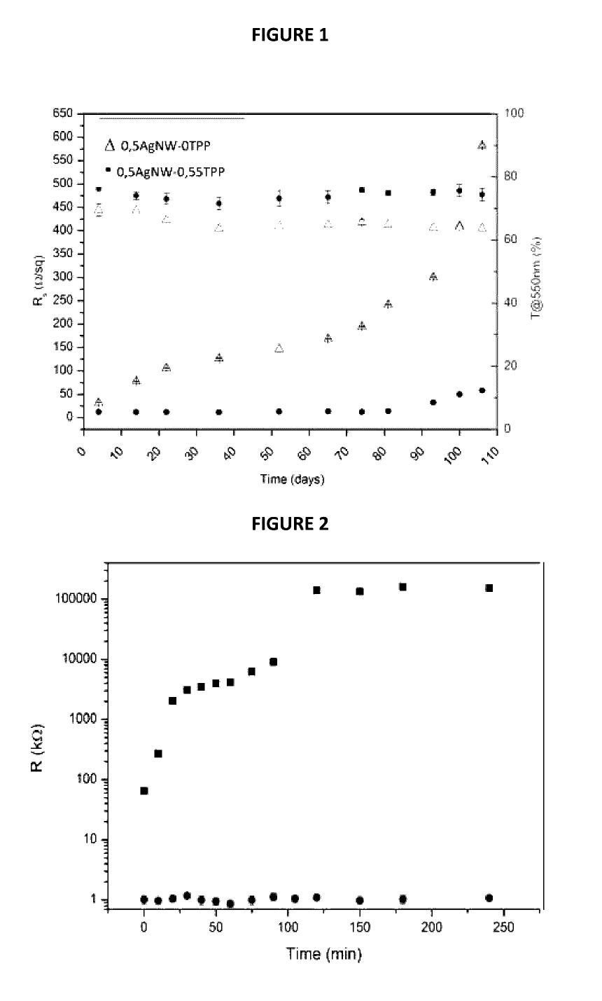

The corresponding results are given by FIG. 1 annexed on which the sheet resistivity (in Ohms/sq) and transmittance (in %) are expressed as a function of time (in days). On this figure, the two higher curves correspond to transmittance while the two lower curves correspond to sheet resistivity. For each, the triangles correspond to the measurements made on the 0.5AgNW-0TPP film not forming part of the invention while the dark dots correspond to the 0.5AgNW-0.55TPP film according to the invention.

This figure clearly shows an increase of the sheet resistivity when the nanowires are not coated with TPP (0.5AgNW-OTTP film not forming part of the present invention). In addition, it can be concluded that the presence of TPP doesn't affect the transmittance which is comparable for materials with or without TPP, films made of TPP protected nanowires (0.5AgNW-0.55TPP) exhibit a constant resistivity as a function of time.

The resistance to accelerated oxidation was tested on films 0.1AgNW-0TPP and 0.1AgNW-0.11TPP.

The method to test the resistance of the films to accelerated oxidation consists in depositing films on an anodic aluminium oxide (AAO) membranes and then to expose them to nitric acid vapours. Mother solutions of fuming nitric acid in water from 0.001 to 0.1M are prepared. A small amount of the mother solution is placed in a petri Dish at the bottom of a dessicator before putting the films in the latter. Films are taken out of the dessicator to carry out measurements before putting them back in the dessicator. The small amount of nitric acid solution is replaced every time the samples are taken out.

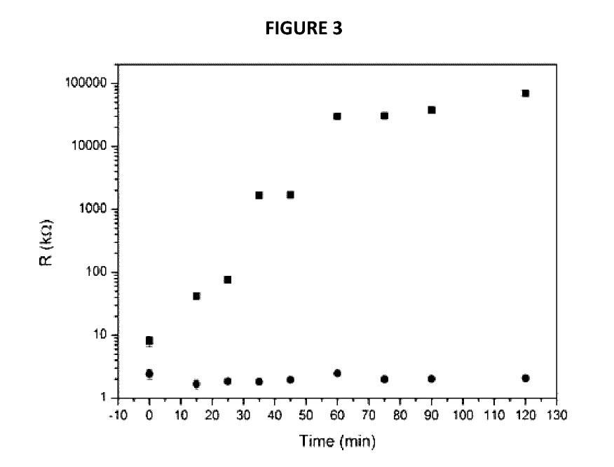

The results are reported in FIGS. 2 and 3 annexed on which the resistance to accelerated oxidation (in kOhms: kΩ) is given as a function of time (in min). FIG. 2 represents the evolution in time of the resistance of the 0.1AgNW-0TPP (dark squares) and 0.1AgNW-0.11TPP (dark dots) films exposed to 0.005 M nitric acid vapours and FIG. 3 represents the evolution in time of the resistance of the 0.1AgNW-0TPP (dark squares) and 0.1AgNW-0.11TPP films (dark dots) exposed to 0.01 M nitric acid vapours.

FIGS. 2 and 3 clearly show that the 0.1AgNW-0TPP film not forming part of the invention gets oxidized very quickly. Indeed its electrical resistance increases by several orders of magnitude after a few hours (from 10 kQ to 10⁵ kΩ). By contrast, the resistance of the 0.1AgNW-0.11TPP film according to the present invention remains constant in the same conditions, even after several hours in this highly oxidative medium.

The above detailed results clearly demonstrate the efficacy of the method of the invention at protecting AgNW against oxidation, even in highly oxidative conditions.

1. A method for producing a transparent and conductive auto-supported silver nanowire film, said method comprising at least the following steps:
A) a first step of preparing a dispersion of silver nanowires in a liquid medium comprising at least one solvent and triphenylphosphine (TPP) or a derivative thereof,
B) a second step of depositing the dispersion obtained in step A) onto a substrate to obtain an assembly comprising a silver nanowire film supported on said substrate,
C) a third step of drying the assembly obtained in step B) to obtained a dried assembly,
D) a fourth step of separating the silver nanowire film from the substrate of the dried assembly obtained in step C) to obtain a transparent and conductive auto-supported silver nanowire film.

2. The method according to claim 1, wherein silver nanowires used according to step A) are chosen among those having a mean diameter ranging from 5 to 200 nm and a length ranging from 1 to 100 μm.

3. The method according to claim 1, wherein the liquid medium used to disperse the silver nanowires during step A) is chosen among water, isopropyl alcohol, ethylene glycol and epoxy resin.

4. The method according to claim 1, wherein the amount of silver nanowires in the dispersion of step A) varies from 0.1 to 4 mg·mL⁻¹.

5. The method according to claim 1, wherein the amount of triphenylphosphine in the dispersion of step A) varies from 0.05 to 2 mg·mL⁻¹.

6. The method according to claim 1, wherein the weight ratio of silver nanowires to TPP varies from about 2:1 to 1:2.

7. The method according to claim 1, wherein the substrate is a porous filter and step B) is carried out by filtering of the dispersion obtained in step 1) onto said porous filter.

8. The method according to claim 7, wherein the porous filter is an anodized aluminum oxide (AAO) membrane.

9. The method according to claim 1, wherein the drying of step C) is performed by heat treatment of the assembly obtained in step B) in air, at a temperature ranging from 60 to 90° C., and for a period of time varying from 5 to 30 minutes.

10. The method according to claim 8, wherein the fourth step of separating the silver nanowires film from the substrate is performed by dissolving the substrate of the dried assembly obtained in step C) in a dissolving medium.

11. A transparent and conductive auto-supported silver nanowires film directly obtained by the method as claimed in claim 1, wherein said film comprises a web of percolated silver nanowires, and wherein the surface of said nanowires is coated by an oxidation resistant layer comprising triphenylphosphine or a derivative thereof.

12. The film of claim 11, wherein said film has a thickness ranging from 10 to 300 nm.

13. The auto-supported silver nanowires film as defined in claim 11, said film configured to be employed as a transparent and flexible electrode in an electric device.

14. The auto-supported silver nanowires film of claim 13, wherein said auto-supported silver nanowires film is configured to be employed as a transparent and flexible electrode in a photovoltaic cell, in plasma screens, in liquid crystals displays, in touch screens, or in organic light-emitting devices.

15. An electric device comprising at least one auto-supported silver nanowires film as defined in claim 11, as a transparent and flexible electrode.
